(19) United States
(12) Patent Application Publication
(10) Pub. No.: US 2025/0167050 A1
(43) Pub. Date: May 22, 2025

(54) LOCAL THERMAL SENSING FOR SYSTEM MONITORING AND CONTROL

(71) Applicant: Advanced Micro Devices, Inc., Santa Clara, CA (US)

(72) Inventors: Srividhya Venkataraman, Santa Clara, CA (US); Ravinder Reddy Rachala, Austin, TX (US); Samuel Naffziger, Fort Collins, CO (US); Thomas D. Burd, Santa Clara, CA (US); Phong T. Phan, Austin, TX (US)

(73) Assignee: Advanced Micro Devices, Inc., Santa Clara, CA (US)

(21) Appl. No.: 18/751,812

(22) Filed: Jun. 24, 2024

Related U.S. Application Data
(60) Provisional application No. 63/601,630, filed on Nov. 21, 2023.

(51) Int. Cl. H01L 21/66

(52) U.S. Cl. CPC H01L 22/12; H01L 22/34

(57) ABSTRACT

A network of thermal sensors can be integrated within a semiconductor chip in a manner effective to provide local temperature monitoring and dynamic control of an associated device or system. The thermal sensors can include small area thermal ring oscillators located proximate to the core of a central processing unit (CPU), for example, and can be disposed on the chip at locations based on a designed output power density and attendant thermal gradients encountered during operation. In certain implementations, the presently-disclosed sensor configuration can be used to measure deviation from set threshold temperatures. Closed-loop control can be implemented to mitigate performance loss while adjusting the clock speed of the CPU independent of the system management unit.

### CROSS-REFERENCE TO RELATED APPLICATION

This application claims the benefit of priority under 35 U.S.C. § 119 (e) of U.S. Provisional Application No. 63/601,630, filed Nov. 21, 2023, the contents of which are incorporated herein by reference in their entirety.

### BACKGROUND

Approaches to thermal management are ubiquitous within the microprocessor industry where rapid performance growth has been accompanied by an increase in transistor density and an attendant increase in heat generation within electronic packages. Absent effective solutions, excessive heat retention and large thermal gradients can adversely impact the performance and reliability of semiconductor devices.

### BRIEF DESCRIPTION OF THE DRAWINGS

The accompanying drawings illustrate a number of example implementations and are a part of the specification. Together with the following description, these drawings demonstrate and explain various principles of the present disclosure.

FIG. 1 is a schematic illustration of an example thermal sensing apparatus according to some implementations.

FIG. 2 is a schematic illustration of an example thermal sensing apparatus according to further implementations.

FIG. 3 is a schematic diagram of a semiconductor chip incorporating multiple instances of a thermal sensor according to some implementations.

FIG. 4 is a schematic diagram illustrating hot spots on the semiconductor chip of FIG. 3 according to particular implementations.

FIG. 5 illustrates aspects of a sensor architecture for evaluating the local temperature of a semiconductor chip according to further implementations.

FIG. 6 is a stacked system architecture including a plurality of thermal sensors configured to support localized power control according to certain implementations.

FIG. 7 is a flowchart illustrating an example method of operation of a system having local thermal sensing and local power control according to some implementations.

Throughout the drawings, identical reference characters and descriptions indicate similar, but not necessarily identical, elements. While the example implementations described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

Disclosed are a methodology and system for determining chip temperatures during operation. More specifically, a real-time model can be used to evaluate the temperatures of sensor-inaccessible target areas on a chip using thermal data from adjacent accessible locations. Target area temperatures can be used to control the operation of an associated device.

Thermal sensors, such as thermal ring oscillators, can be formed directly on a semiconductor chip and used to measure the chip's temperature profile during use. Sensor output can be integrated into a feedback loop that is configured to modify the chip's operation, including its power consumption while running various processes. Efficient thermal monitoring can be used to maintain power consumption and chip temperatures within their specifications, particularly in systems including processors having a large dynamic power range (e.g., approximately 1 W to approximately 25 W).

In some systems, it can be challenging to obtain accurate thermal readings because the thermal sensors cannot be placed directly in the hottest regions of the chip due to competing real estate interests such as with performance-critical logic. Moreover, the placement of larger sensors in certain locations can adversely interfere with the chip's local thermal equilibrium environment. As a result, thermal sensors are often located outside of critical and dense areas of a chip, which can be beneficial for floor-planning, but can lead to significant errors in reported temperatures.

As integration density increases, accurate and effective thermal management will be increasingly important. Notwithstanding recent developments, it would be advantageous to have accurate and relevant thermal data that can be used to guide efficient and reliable chip function, including reduced margining and improved dynamic voltage and frequency scaling (DVFS). According to various implementations, the use of digital MOS-based thermal sensors (in lieu of comparative analog thermal sensors) may facilitate effective placement of such sensors in critical areas of a semiconductor chip, thus realizing improvements in thermal monitoring in addition to simplifying design and manufacture.

Effective thermal management can beneficially impact the operation of high-performance designs, particularly 3D stacked architectures. According to some implementations, intra-core temperature monitoring can be used to locally decrease switching activity in a region where an exceptionally high temperature has been detected. By way of example, intra-core temperature monitoring can be used to determine threshold conditions for alarm triggers, which can initiate electrical design current (EDC) throttle mechanisms to slow dispatch speeds and regulate local hotspots and associated temperature gradients.

Disclosed are a system and method that utilize multiple thermal sensors to evaluate temperature information within critical regions of a semiconductor chip. A network of thermal sensors can be integrated within a semiconductor chip in a manner effective to provide local temperature monitoring and dynamic control of an associated device or system. The thermal sensors can include small area thermal ring oscillators located proximate to identified hotspots of a central processing unit (CPU), for example, and can be disposed on the chip at locations based on a designed output power density and attendant thermal gradients anticipated during operation. In certain examples, the presently-disclosed sensor configuration can be used to measure deviation from set threshold temperatures. Closed-loop control can be implemented to mitigate performance loss while adjusting the clock speed and/or power consumption through localized throttling mechanisms to decrease activity in regions of the CPU pipeline (e.g., decode, execute, etc.) independent of the system management unit.

The disclosed methodology can be used with any suitable type or form of semiconductor. For example, the system and methods may be used with various processor integrated circuits, including CPUs, GPUs, FPGAS, ACAPs, neural accelerators, analog devices, memories, etc., and in both low-power embedded chips and high-power server and HPC chips. The disclosed systems and methods may also be used with memory integrated circuits, such as random access memory (RAM), dynamic RAM (DRAM), read-only memory (ROM), cache memory, flash memory, etc. Additional or alternatively, the approaches of this disclosure may be used with storage device, peripheral interfaces, wireless interfaces, controllers, etc. Moreover, these approaches are compatible with silicon-based integrated circuits as well as with integrated circuits manufactured with other semiconductors, including GaAs, GaN, and the like. These approaches are also compatible with discrete semiconductor chips, systems on a chip (e.g., a semiconductor chip that includes one or more of a processor integrated circuit, a memory integrated circuit, etc.), an application-specific integrated circuit (ASIC), etc.

Disclosed are methods and structures for thermally monitoring and controlling the operation of an integrated circuit. An exemplary method includes forming a plurality of thermal sensing elements at predetermined locations on a semiconductor chip (e.g., within semiconductor material of the semiconductor chip) proximate to a plurality of respective target locations, measuring a temperature of the semiconductor chip at each target location using a corresponding one of the plurality of thermal sensing elements, and determining an operating condition of the semiconductor chip using the temperatures measured at each of the target locations. Local temperature monitoring can be implemented to provide effective CPU thermal management, for example.

Based on the one or more temperatures measured at one or more respective target locations, the operation of the semiconductor chip may be altered. Altering operation of the semiconductor chip may include one or more of changing an operating or driving voltage, changing clock frequency, and changing a number of instructions executed per cycle.

In particular implementations, the thermal sensing elements can include thermal ring oscillators that are integrated into the chip. The target location can correspond to a known or suspected hotspot, such as within one or more regions of a CPU core. For example, Applicants have measured thermal gradients in processor cores in excess of 20° C. over distances of approximately 100 micrometers. Temperature readings from one or more of the individual sensing elements can be combined with temperature gradients between pairs of sensing elements to generate real time temperature data for the target location. In certain models, the various temperature gradients can be weighted by calibration constants to provide an accurate hotspot prediction.

According to a further example, the temperature at the target location can be determined from a temperature measured at a plurality of the predetermined locations, and operational information for the semiconductor chip selected from a performance counter, an activity counter, a dynamic processor state, and/or configuration information. In some examples, the temperature of the semiconductor chip at each target location can be measured simultaneously.

According to various implementations, the thermal sensors can be sized and dimensioned to measure temperatures locally across a semiconductor chip. By way of example, each sensor can be dimensioned to have an area that is less than the area of approximately 1000 logic gates located on the chip, e.g., a sensor area equal to the area of 100, 200, 500, or 1000 logic gates, including ranges between any of the foregoing values. An individual thermal sensor, such as thermal ring oscillator, can have a linear dimension of less than approximately 50 micrometers, e.g., 4, 5, 10, 12, 15, 20, 30, 40, or 50 μm, for example, and a corresponding areal dimension of less than approximately 2500 μm², e.g., 20, 25, 30, 40, 50, 100, 200, 300, 400, 500, 1000, 2000, or 2500 μm², including ranges between any of the foregoing values.

A further method may include forming a plurality of thermal sensing elements on a semiconductor chip, measuring a temperature of the semiconductor chip corresponding to each respective thermal sensing element, and determining an operating condition of the semiconductor chip using the measured temperatures.

An associated system includes a semiconductor chip having a plurality of target locations, and a plurality of thermal sensing elements located on the semiconductor chip proximate to respective ones of the target locations. The system is configured to utilize multiple thermal sensor readings, and based on a function of the readings, cause operation of the semiconductor chip to be adjusted in a thermally beneficial way, such as by decreasing power to continue operation within an established thermal budget, or increasing power to convert available thermal headroom into improved higher performance. Further example operational adjustments can include one or more of decreasing voltage, decreasing clock frequency, and decreasing a number of instructions executed per cycle. The system can include appropriate interfaces to report the measured temperatures to software layers, including OS, hypervisor, firmware, and performance/system monitoring tools. A method of operation includes targeted power reduction and attendant fine-grained temperature control to inhibit the formation of localized hot spots within a semiconductor chip.

Placement locations of the thermal sensors can be informed by the power density distribution associated with given CPU design. For instance, one or more thermal sensors can be located proximate to a known or anticipated hot spot. During operation, the thermal sensors can be configured to measure temperatures locally across a chip. Using this temperature information, the operation of a CPU or other element can be tuned to mitigate large temperature gradients or thermal spikes without excessively compromising system efficiency. That is, using localized temperature information, localized and targeted power reduction can be implemented in real time to provide effective thermal management resulting in improved system performance.

An example method may include forming a plurality of thermal sensing elements at predetermined locations on a semiconductor chip proximate to a plurality of respective target locations, measuring a temperature of the semiconductor chip at each target location using a corresponding one of the plurality of thermal sensing elements, and determining an operating condition of the semiconductor chip using the temperatures measured at each of the target locations, where measuring the temperature of the semiconductor chip includes measuring an output from each of the thermal sensing elements and evaluating the measured outputs using processor logic.

A further example method may include forming a plurality of thermal sensing elements on a semiconductor chip, measuring a temperature of the semiconductor chip corresponding to each respective thermal sensing element, and determining an operating condition of the semiconductor chip using the measured temperatures, where measuring a temperature of the semiconductor chip includes measuring a plurality of temperatures at each thermal sensing element at a measurement interval of less than approximately 20 microseconds (e.g., less than approximately 20, 10, 5, or 1 microsecond, including ranges between any of the foregoing values).

Features from any of the implementations described herein can be used in combination with one another in accordance with the general principles described herein. These and other implementations, features, and advantages will be more fully understood upon reading the following detailed description in conjunction with the accompanying drawings and claims.

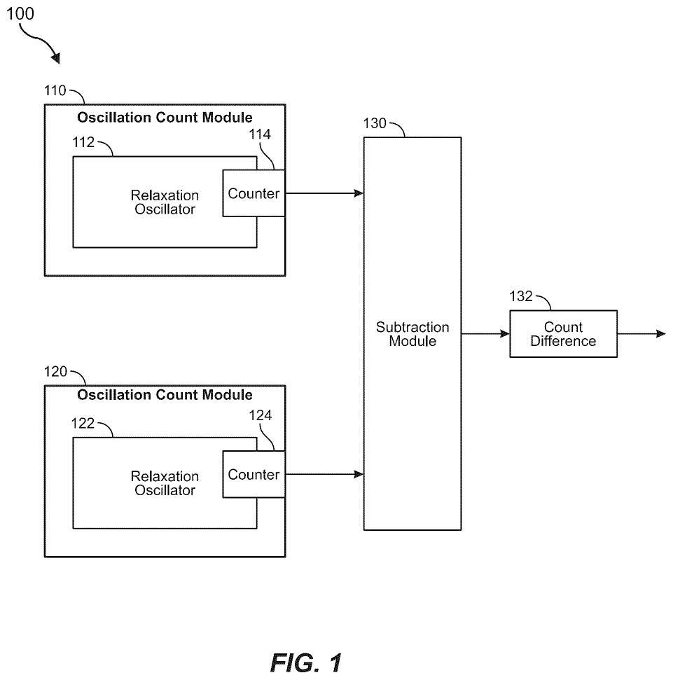

The present disclosure is generally directed to the thermal management of a semiconductor device or chip, and more particularly to a sensing infrastructure for directly assessing the temperature of a chip during use accordingly adjusting operation of the device or chip. Aspects of the sensing architecture according to particular implementations together with an exemplary method of operation are described with reference to FIGS. 1-7.

FIG. 1 is a schematic illustration of an example apparatus for thermal sensing. Apparatus 100 can include one or more modules for performing one or more tasks, such as an oscillation count module 110, an oscillation count module 120, and a subtraction module 130. In certain implementations, one or more of the modules described herein can represent one or more circuits that, when activated, can perform or cause other parts of a computing device to perform one or more tasks. Although illustrated as separate components, one or more of the modules 110, 120, 130 in FIG. 1 can represent portions of a single module.

In some implementations, oscillation count module 110 can include a relaxation oscillator 112 and oscillation count module 120 can include a relaxation oscillator 122. As used here in the term “relaxation oscillator” can refer to any circuit that produces an oscillating signal that is affected by the temperature of the circuit. Thus, relaxation oscillators 112 and 122 can represent any type of relaxation oscillator whose behavior varies under different temperature conditions. In this regard, while many of the disclosed examples refer to relaxation oscillators, it will be appreciated that in various instantiations, oscillators of various topologies (and not only, e.g., a relaxation topology) can be used.

In some implementations, relaxation oscillators 112 and 122 can include leakage-based relaxation oscillators that leak charge. Thus, for example, relaxation oscillators 112 and 122 can oscillate at higher frequencies when leaking charge more quickly. In addition, relaxation oscillators 112 and 122 can leak charge more quickly at higher temperatures. Accordingly, relaxation oscillators 112 and 122 can oscillate at higher frequencies at higher temperatures.

While relaxation oscillators 112 and 122 can vary behavior based on temperature conditions, other factors can influence the behavior of relaxation oscillators 112 and 122. For example, in some implementations, variations in supply voltage to relaxation oscillators 121 and 122 can impact their respective frequencies of oscillation.

Relaxation oscillators 112 and 122 can operate at the same or different supply voltages. In addition, relaxation oscillators 112 and 122 can be configured to oscillate at different rates at the same temperature. For example, in some implementations, relaxation oscillators 112 and 122 can include voltage comparators that use a different reference voltage. As used herein, the term “voltage comparator” can refer to any device that compares two voltages (e.g., a primary voltage and a reference voltage) and outputs a signal representative of the difference. Thus, one relaxation oscillator can be configured as a control oscillator to a second relaxation oscillator that is configured to measure temperature.

According to exemplary implementations, a difference in behavior between relaxation oscillator 112 and relaxation oscillator 122 can be correlated to a local temperature. This difference in behavior can be evaluated by subtraction module 130. In this regard, oscillation count module 110 can include a counter 114 that counts oscillations of relaxation oscillator 112 and oscillation count module 120 can include a counter 124 that counts oscillations of relaxation oscillator 122. Subtraction module 130 can subtract the value of counter 124 from the value of counter 114 to produce a count difference 132 that represents a difference in oscillation frequencies between relaxation oscillators 112 and 122 and, therefore, can correlate with temperature. As used herein the term “counter” can refer to any circuit that provides, as output, one or more signals representing a count of one or more qualifying input conditions. For example, the term counter can refer to a ripple counter.

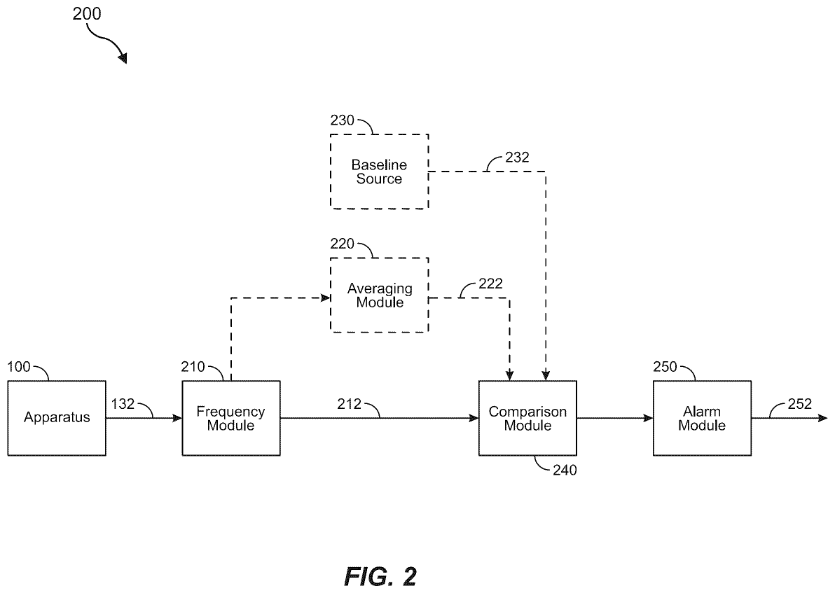

Referring to FIG. 2, shown is a schematic diagram of a further apparatus configured for relaxation oscillator-based thermal sensing. Thermal sensor 200 can include apparatus 100, a frequency module 210, a comparison module 240, and/or an alarm module 250. In addition, in some variations, thermal sensor 200 can include an averaging module 220 and/or a baseline source 230.

Frequency module 210 can produce a frequency based on count difference 132. For example, frequency module 210 can divide count difference 132 by a period of time to output a current temperature value 212. In some implementations, frequency module 210 can divide count difference 132 into periods to produce a frequency value that acts as a proxy for temperature by periodically resetting counters 114 and 124 of apparatus 100. For example, frequency module 210 can provide a frequency value every ten microseconds or more frequently, every five microseconds or more frequently, every two microseconds or more frequently, etc., and then reset counters 114 and 124. In some examples, frequency module 210 can produce a value representing a current frequency difference between relaxation oscillators 112 and 122.

In some implementations, comparison module 240 can compare current temperature value 212 with one or more other temperature values. For example, an averaging module 220 can average sample frequency values from frequency module 210 over a period of time to produce an average temperature value 222. Thus, for example, averaging module 220 can calculate a running average of the last N samples, where N can be any suitable value, to calculate a running average over the last five samples, the last hundred samples, etc. In some implementations, N can be a programmable value. In one variation, comparison module 240 can compare current temperature value 212 with average temperature value 222. In another variation, comparison module 240 can compare current temperature value 212 with the baseline temperature value 232 from baseline source 230. For example, baseline source 230 can be a known “cold spot” on a chip with a reliably cold and/or stable temperature. In some examples, baseline temperature value 232 can be written to a register space for use in thermal sensor 200. In some variations, baseline temperature value 232 can be produced by an instance of apparatus 100 at baseline source 230.

Based on the results from comparison module 240, alarm module 250 can generate an alarm signal 252. For example, if current temperature value 212 exceeds a reference value (e.g., average temperature value 222 or baseline temperature value 232) by more than a predetermined threshold, alarm module can generate an alarm signal 252.

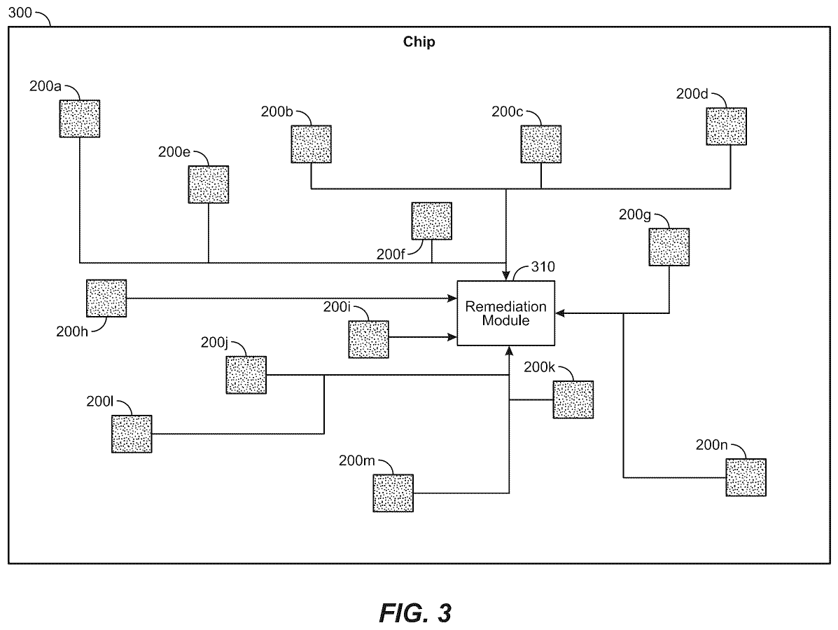

FIG. 3 is a schematic diagram of an example chip incorporating multiple instances of thermal sensor 200. Chip 300 can be any type of device that can be subject to thermal monitoring and/or management. Examples of chip 300 include, without limitation, a processor, a processor core, a hardware accelerator, a system-on-chip, a graphics processing unit, a field-programmable gate array, an application-specific integrated circuit, a random-access memory device, a solid-state device, and the like.

As shown in FIG. 3, instances 200a-n of thermal sensor 200 can be distributed across chip 300. As will be appreciated, whereas instances 200a-n are depicted in FIG. 3, a chip can include any suitable number of thermal sensors. By way of example, a chip can include 5 or more, 10 or more, 15 or more, 20 or more, 25 or more, or 30 or more thermal sensors. In some variations, a high number of thermal sensors 200 can be integrated on a single chip due to the form factor of each individual sensor.

Chip 300 can include a remediation module 310. In some examples, remediation module 310 can receive one or more alarm signals from one or more instances 200a-n of thermal sensor 200 when the corresponding instance senses a sufficiently elevated temperature. In response, remediation module 310 can perform one or more remediation actions. For example, remediation module 310 can reduce a clock speed of chip 300 to decrease a temperature of chip 300. Additionally or alternatively, remediation module 310 can decrease a voltage supply to chip 300. In some implementations, remediation module 310 can throttle at least one task performed by chip 300 (e.g., one or more instructions to be executed by chip 300).

In some implementations, remediation module 310 can represent one or more circuits that, when activated, can perform at least a portion of one or more of the tasks described and/or that can send a signal to another device to perform at least a portion of one or more of the tasks described. In some variations, at least a portion of remediation module 310 can be implemented as computer-executable instructions, e.g., stored in a memory device and executed by a hardware processor. Additionally or alternatively, remediation module 310 can interface with the memory device and/or hardware processor that store and execute computer-executable instructions to perform one or more thermal remediation tasks.

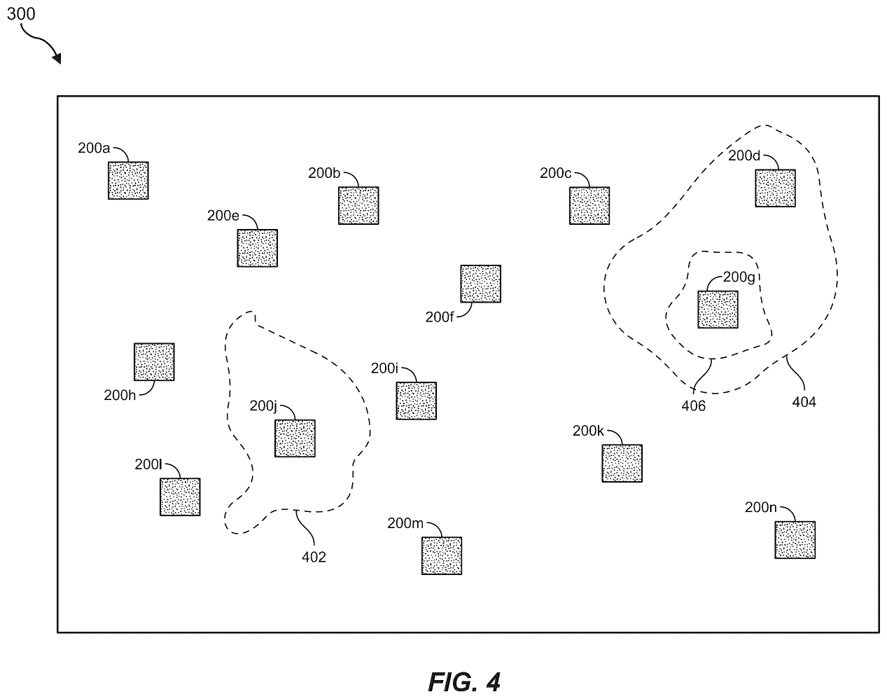

FIG. 4 is a schematic diagram illustrating hotspots on example chip 300 of FIG. 3. As shown in FIG. 4, chip 300 can include multiple hotspot areas, such as a hotspot 402, a hotspot 404, and a hotspot 406. In one example, hotspot 406 can represent a higher temperature than hotspots 402 and 404.

As used herein, the term “hotspot” can refer to any area within a device where the temperature of the area can potentially affect the reliability and/or performance of the device, can indicate a potential future impact on the reliability and/or performance of the device, and/or that is above a predetermined threshold. As can be appreciated from FIG. 4, while hotspots 402, 404, and 406 can be detected and remediated by the apparatuses and systems described herein, in a comparative variation having fewer thermal sensors, hot spots 402, 404 and/or 406 could be overlooked until a temperature of the chip is undesirably greater. For example, in a variation where the only thermal sensor on chip 300 is instance 200f, or where the only thermal sensors on chip 300 are instances 200b, 200i, and 200k, hotspots 402, 404, and 406 could go undetected until reaching respective temperatures above a predetermined threshold. In accordance with particular implementations, a higher density of thermal sensors can potentially allow for more expedient, efficient and/or effective thermal management.

In some examples, a thermal management system (including, e.g., remediation module 310 of FIG. 3) can respond to alarms generated by instances 200a-n based at least in part on (a) the number of instances generating alarms (e.g., within a given temporal window), (b) the magnitude of the hotspots, and/or (c) the absolute and/or relative locations of the instances that generate the alarms. Thus, for example, in some variations a thermal management system can be configured to perform one or more remediation action at a lower temperature threshold, with a higher degree of response (e.g., a greater reduction of the clock rate and/or for a longer period of time, a greater reduction to voltage and/or for a longer period of time, a greater number of instructions throttled and/or for a longer period of time, etc.) based on there being, e.g., three sensors detecting hotspots rather than just one.

In one variation, a thermal management system can, based on the proximity of instances 200d and 200g, infer hotspot 404 to be relatively large (and thus, e.g., more challenging to dissipate). In response, the thermal management system can perform one or more remediation actions at a lower temperature threshold than otherwise and/or perform them with a higher degree of response.

In some variations, a thermal management system can select a type and/or degree of remediation action based on the location of thermal sensors reporting hotspots. For example, a thermal management system can, based on the location of instance 200d on chip 300, reduce clock speed rather than voltage (or vice versa) in response to an alarm from instance 200d.

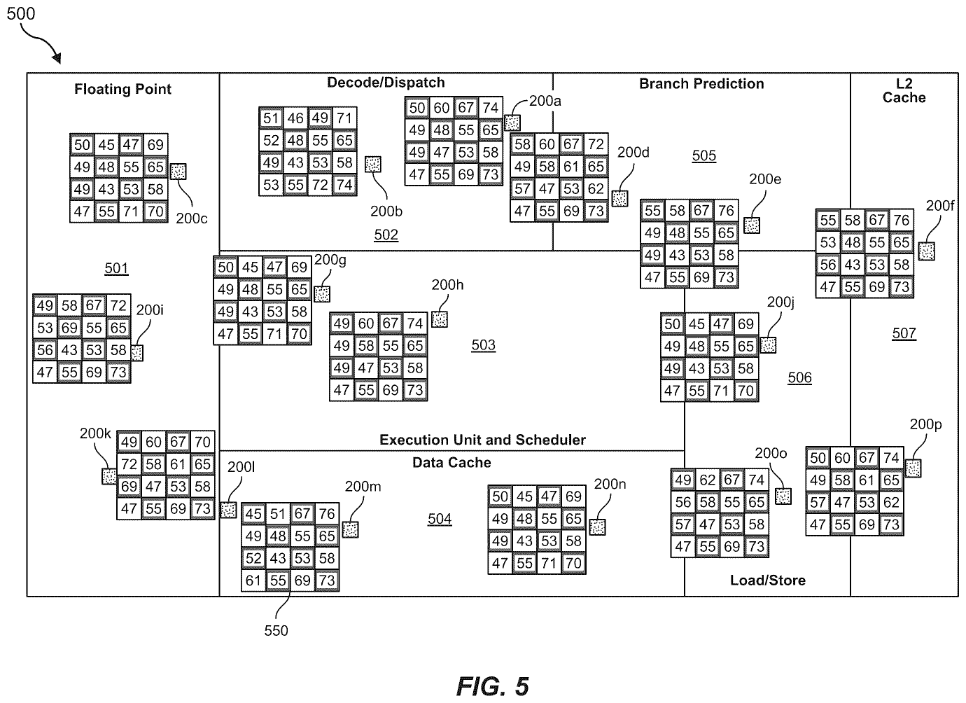

Turning to FIG. 5, an example CPU 500 includes various chip-based components, including a floating point unit 501, a decode/dispatch unit 502, an execution unit and scheduler 503, a data cache 504, a branch prediction unit 505, a load/store unit 506, and an L2 cache 507. A plurality of thermal sensors 200a-p are non-invasively co-integrated with the CPU. According to some implementations, one or more of the sensors 200a-p can be incorporated into each chip-based component, and each sensor can be located proximate to an identified hot spot within the CPU. Intra-component or inter-component thermal maps 550 can be used to chronicle local temperatures and temperature gradients, and can be used to inform the placement of the sensors 200a-p. The sensors can be arranged to provide a spatially-localized temperature profile during operation.

Real-time temperature data can be used to control operation of the CPU, i.e., to maximize performance while operating in accordance with a predetermined thermal budget. By way of example, a thermal sensor array can provide a localized temperature map that can be used to locally control power utilization. This can facilitate device operation where thermal management and performance are synergistic. That is, according to some implementations, local (rather than global) thermal remediation can be applied to address a local hotspot, which can avoid an over response to a thermal spike and promote efficient operation.

In certain instantiations, thermal sensors can be located in a configuration that is reflective of the power density distribution of a device. That is, relative to an overall placement of thermal sensors, a greater number of thermal sensors can be located proximate to a known hotspot within the device in order to increase the fidelity of temperature sensing in that region.

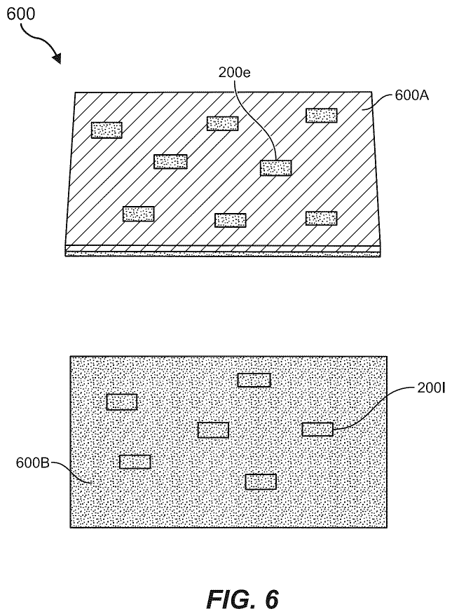

Referring to FIG. 6, a stacked die configuration 600 includes a first die 600A overlying a second die 600B. Sensors, such as sensor 200e in first die 600A and sensor 2001 in second die 600B, can be integrated into each respective layer where the sensor location can be determined according to the power density distribution in that layer as well as in adjacent layers.

Although thermal sensor configurations have been described in the context of power management for a semiconductor chip having a central processing unit, it will be appreciated that such thermal sensing and system operation can be applied to other high performance integrated circuits.

For example, the thermal sensing and system operations described here can apply to a system having a memory integrated circuit and a processing integrated circuit communicatively coupled to the memory integrated circuit. The memory integrated circuit is any type or form of memory device (e.g., RAM, ROM, a cache, etc.) and the processing integrated circuit is any type or form of microprocessor (e.g., a CPU, a GPU, an ASIC, etc.). Such a system includes a set of thermal sensing elements having one or more sensing elements, and each thermal sensing element in the set is a digital MOS-based element. These sensing elements are located in semiconductor material of the memory integrated circuit and/or semiconductor material of the processing integrated circuit. In some examples, semiconductor material of an integrated circuit may be any semiconductor material of a chip in which the integrated circuit is formed.

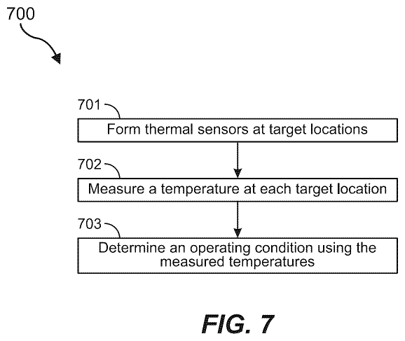

Disclosed is a system design configured to provide CPU-level thermal sensing and thermal management. An example method of operation, including the evaluation and control of the temperature profile of a CPU, is depicted in FIG. 7. The disclosed method 700 includes forming a plurality of thermal sensing elements at predetermined locations on a semiconductor chip proximate to a plurality of respective target locations (701), measuring a temperature of the semiconductor chip at each target location using a corresponding one of the plurality of thermal sensing elements (702), and determining an operating condition of the semiconductor chip using the temperatures measured at each of the target locations (703).

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

The term “approximately” in reference to a particular numeric value or range of values can, in certain implementations, mean and include the stated value as well as all values within 10% of the stated value. Thus, by way of example, reference to the numeric value “50” as “approximately 50” can, in certain implementations, include values equal to 50±5, i.e., values within the range 45 to 55.

The term “substantially” in reference to a given parameter, property, or condition can mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition can be at least approximately 90% met, at least approximately 95% met, or even at least approximately 99% met.

It will be understood that when an element such as a layer or a region is referred to as being formed on, deposited on, or disposed “on” or “over” another element, it can be located directly on at least a portion of the other element, or one or more intervening elements can also be present. In contrast, when an element is referred to as being “directly on” or “directly over” another element, it can be located on at least a portion of the other element, with no intervening elements present.

While various features, elements or steps of particular implementations can be disclosed using the transitional term “comprising,” it is to be understood that alternative implementations, including those that can be described using the transitional phrases “consisting of” or “consisting essentially of,” are implied. Thus, for example, implied alternative implementations to a semiconductor substrate that comprises or includes silicon include implementations where a semiconductor substrate consists essentially of silicon and implementations where a semiconductor substrate consists of silicon.

What is claimed is:

1. A method comprising:
forming a plurality of thermal sensing elements at predetermined locations on a semiconductor chip proximate to a plurality of respective target locations;
measuring a temperature of the semiconductor chip at each target location using a corresponding one of the plurality of thermal sensing elements; and
determining an operating condition of the semiconductor chip using the temperatures measured at each of the target locations, wherein measuring the temperature of the semiconductor chip comprises:
measuring an output from each of the thermal sensing elements; and
evaluating the measured outputs using processor logic.

2. The method of claim 1, wherein the thermal sensing elements comprise thermal ring oscillators.

3. The method of claim 1, wherein the predetermined locations are determined from a power density distribution of the semiconductor chip.

4. The method of claim 1, wherein the semiconductor chip comprises a central processing unit (CPU).

5. The method of claim 1, wherein at least one of the target locations comprises a hotspot.

6. The method of claim 1, wherein at least one of the target locations is located proximate to a central processing unit.

7. The method of claim 1, further comprising altering operation of the semiconductor chip based on the temperatures at the target locations.

8. The method of claim 7, wherein altering operation of the semiconductor chip comprises one or more of changing voltage, changing clock frequency, and changing a number of instructions executed per cycle.

9. The method of claim 1, wherein the temperature of the semiconductor chip at each target location is measured simultaneously.

10. The method of claim 1, wherein measuring the temperature of the semiconductor chip at each target location comprises measuring the temperatures at each thermal sensing element at a measurement interval of less than approximately 20 microseconds.

11. A system comprising:
a memory integrated circuit;
a processing integrated circuit communicatively coupled to the memory integrated circuit and configured to access data stored in the memory integrated circuit; and
a plurality of thermal sensing elements, each comprising a digital MOS-based element, located within at least one of:
semiconductor material of the memory integrated circuit, or
semiconductor material of the processing integrated circuit.

12. The system of claim 11, wherein:
the plurality of thermal sensing elements are located within the semiconductor material of the processing integrated circuit; and
the processing integrated circuit comprises a central processing unit.

13. The system of claim 12, wherein:
the plurality of thermal sensing elements are located within the semiconductor material of the memory integrated circuit; and
the memory integrated circuit comprises random access memory.

14. The system of claim 11, further comprising:
a system on a chip that comprises the memory integrated circuit and the processing integrated circuit.

15. A semiconductor chip comprising:
an integrated circuit; and
a plurality of thermal sensing elements proximate to the integrated circuit, wherein the thermal sensing elements each comprise a digital MOS-based element.

16. The semiconductor chip of claim 15, wherein the thermal sensing elements comprise ring oscillators.

17. The semiconductor chip of claim 15, wherein each of the plurality of thermal sensing elements is located proximate to a respective hot spot.

18. The semiconductor chip of claim 15, further comprising a remediation module connected to each of the plurality of thermal sensing elements.

19. The semiconductor chip of claim 18, wherein the remediation module is configured to execute one or more thermal remediation tasks.

20. The semiconductor chip of claim 19, wherein the one or more thermal remediation tasks are selected from the group consisting of changing voltage, changing clock frequency, and changing a number of instructions executed per cycle.
